(19) United States
(12) Patent Application Publication
(10) Pub. No.: US 2025/0268070 A1
(43) Pub. Date: Aug. 21, 2025

(54) Display Device

(71) Applicant: LG Display Co., Ltd., Seoul (KR)

(72) Inventor: Junjae Lee, Paju-si (KR)

(21) Appl. No.: 18/946,550

(22) Filed: Nov. 13, 2024

(30) Foreign Application Priority Data
Feb. 16, 2024 (KR) 10-2024-0022861

(51) Int. Cl. H10K 59/80

(52) U.S. Cl. CPC H10K 59/873

(57) ABSTRACT

A display device includes a cover window; a display panel which includes an active area disposed below the cover window and including a plurality of pixels disposed therein, a first non-active area which encloses the active area, and a bending area which extends from one side of the first non-active area to be bent; a frame which is disposed below the display panel and includes a plurality of protrusions disposed on a side surface; and a molding member which is disposed below the cover window along an end of the cover window and is disposed so as to cover a side surface of the display panel, a side surface of the frame in which the plurality of protrusions is disposed, and a part of a bottom surface of the frame.

### CROSS-REFERENCE TO RELATED APPLICATION

This application claims the priority of Republic of Korea Patent Application No. 10-2024-0022861 filed on Feb. 16, 2024, in the Korean Intellectual Property Office, which is hereby incorporated by reference in its entirety.

### BACKGROUND

### Field

The present disclosure relates to a display device, and more particularly, to a display device with an improved bonding strength between components of the display device.

### Description of the Related Art

Currently, as a full-scale information era is entered, a field of a display device which visually expresses electrical information signals has been rapidly developed and studies are continued to improve performances of various display devices such as a thin-thickness, a light weight, and low power consumption.

Among various display devices, a light emitting display device is a self-emitting display device so that a separate light source is not necessary, which is different from the liquid crystal display device. Therefore, the light emitting display device may be manufactured to have light weight and small thickness. Further, since the light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### SUMMARY

An object to be achieved by the present disclosure is to provide a display device which minimizes a size of a bezel area.

Another object to be achieved by the present disclosure is to provide a display device which minimizes or at least reduces separation of components.

Objects of the present disclosure are not limited to the above-mentioned objects, and other objects, which are not mentioned above, can be clearly understood by those skilled in the art from the following descriptions.

According to an aspect of the present disclosure, a display device includes a cover window; a display panel which includes an active area disposed below the cover window and including a plurality of pixels disposed therein, a first non-active area which encloses the active area, and a bending area which extends from one side of the first non-active area to be bent; a frame which is disposed below the display panel and includes a plurality of protrusions disposed on a side surface; and a molding member which is disposed below the cover window along an end of the cover window and is disposed so as to cover a side surface of the display panel, a side surface of the frame in which the plurality of protrusions is disposed, and a part of a bottom surface of the frame.

Other detailed matters of the exemplary embodiments are included in the detailed description and the drawings.

According to the present disclosure, a space required to protect an outside of the display panel is minimized or at least reduced to implement a narrow bezel.

According to the present disclosure, a bonding strength between components of the display device and a molding member is improved to improve the durability of the display device.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1A is a plan view of a display device according to an exemplary embodiment of the present disclosure before bending a display panel;

FIG. 1B is a rear view of a display device according to an exemplary embodiment of the present disclosure;

FIG. 2A is a perspective cross-sectional view of a display device according to an exemplary embodiment of the present disclosure;

FIG. 2B is an enlarged plan view of an area A of FIG. 1B according to an exemplary embodiment of the present disclosure;

FIG. 3A is a cross-sectional view of B-B′ of FIG. 2B according to an exemplary embodiment of the present disclosure;

FIG. 3B is a cross-sectional view of C-C′ of FIG. 2B according to an exemplary embodiment of the present disclosure;

FIG. 3C is a cross-sectional view of D-D′ of FIG. 1B according to an exemplary embodiment of the present disclosure;

FIG. 4 is a perspective cross-sectional view of a display device according to another exemplary embodiment of the present disclosure; and

FIGS. 5A and 5B are cross-sectional views of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

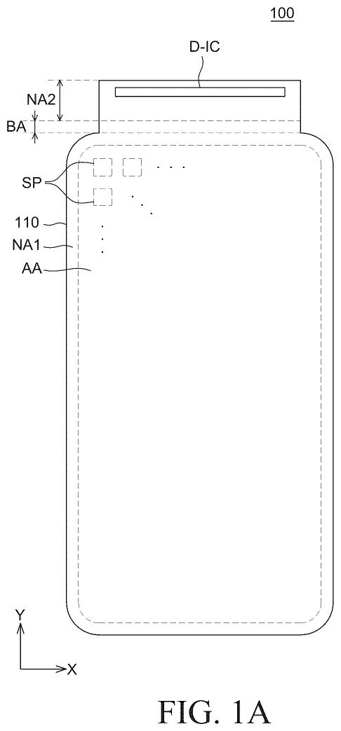

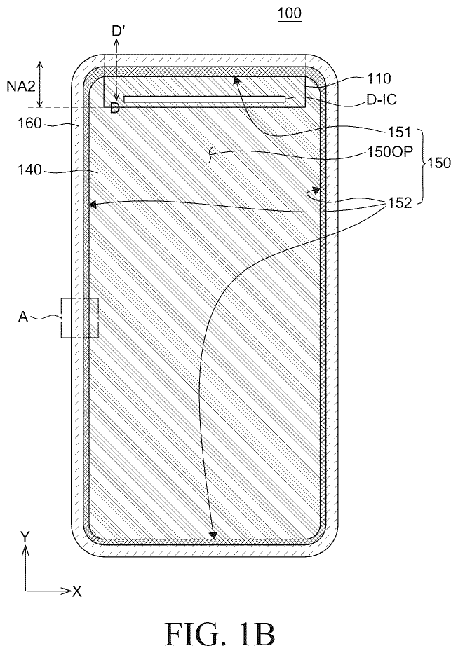

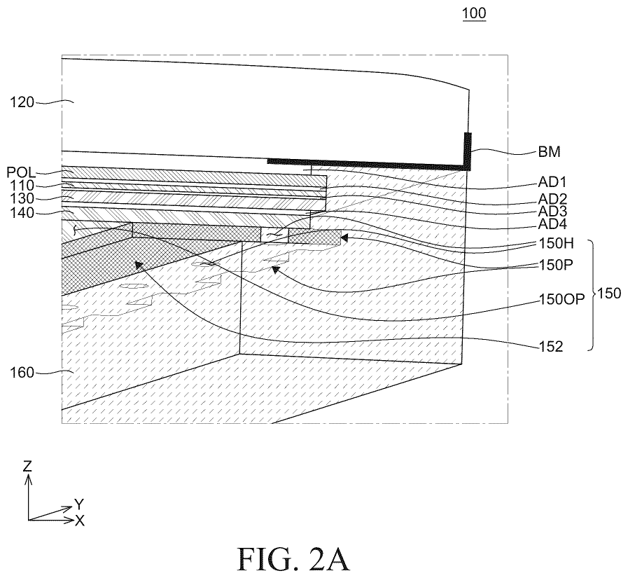

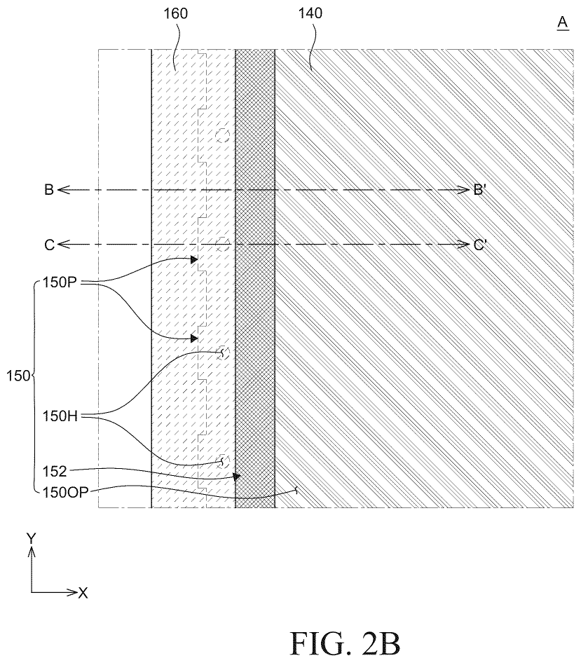

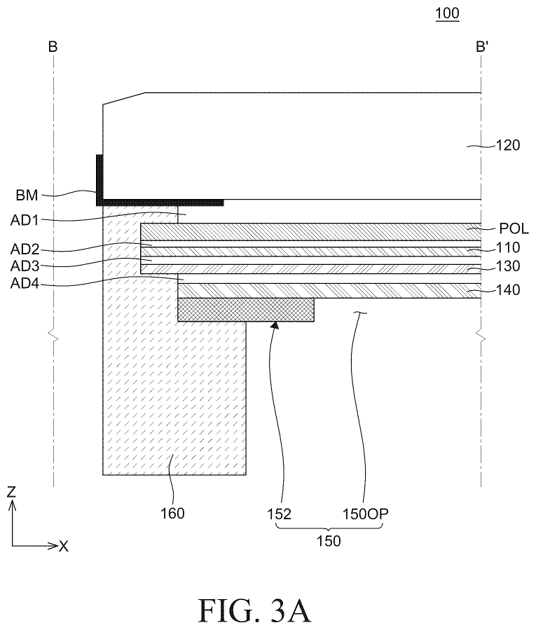

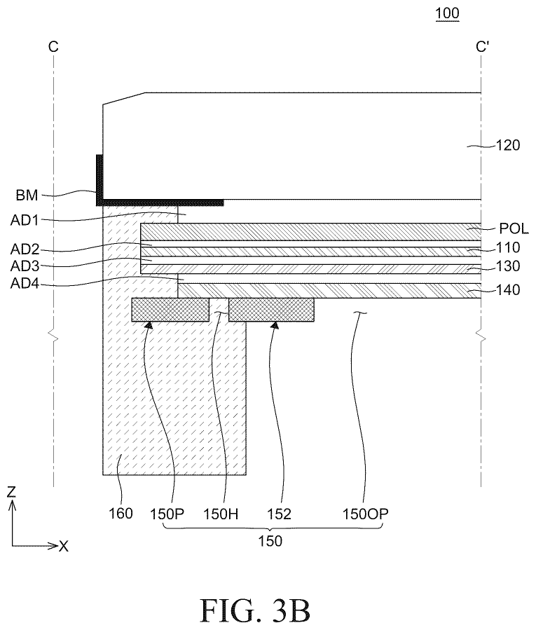

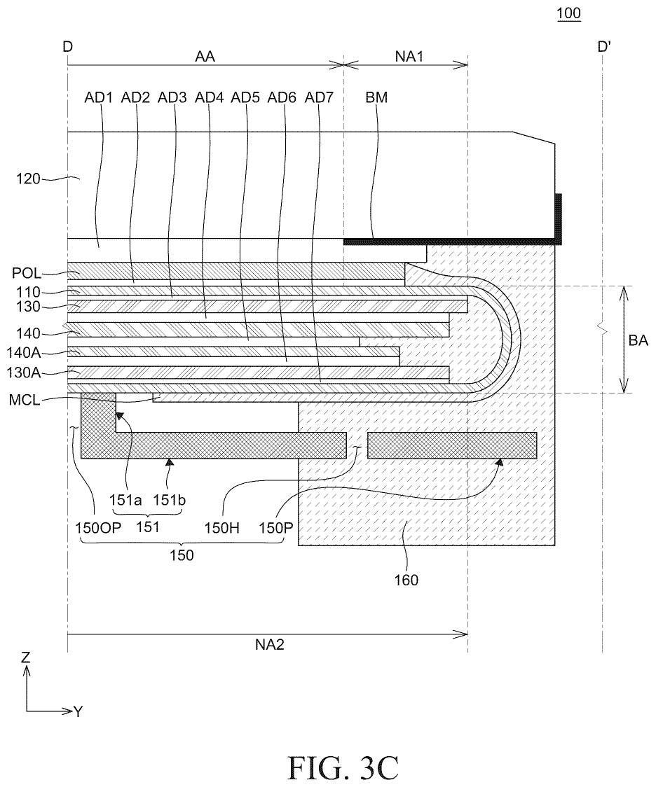

FIG. 1 is a schematic cross-sectional view of a display device according to an exemplary embodiment of the present disclosure. FIG. 1A is a plan view of a display device according to an exemplary embodiment of the present disclosure before bending a display panel. FIG. 1B is a rear view of a display device according to an exemplary embodiment of the present disclosure. FIG. 2A is a perspective cross-sectional view of a display device according to an exemplary embodiment of the present disclosure. FIG. 2B is an enlarged plan view of an area A of FIG. 1B according to an exemplary embodiment of the present disclosure. FIG. 3A is a cross-sectional view of B-B′ of FIG. 2B according to an exemplary embodiment of the present disclosure. FIG. 3B is a cross-sectional view of C-C′ of FIG. 2B according to an exemplary embodiment of the present disclosure. FIG. 3C is a cross-sectional view of D-D′ of FIG. 1B according to an exemplary embodiment of the present disclosure. In FIGS. 1A to 3C, for the convenience of description, among components of a display device 100, a display panel 110, a cover window 120, a back plate 130, a metal plate 140, a frame 150, and a molding member 160 are illustrated. In FIG. 1A, for the convenience of illustration, the hatching of the display panel 110 is omitted. FIG. 2A is a perspective cross-sectional view for the same cross-section as B-B′ of FIG. 2B.

In FIGS. 1A to 3C, a display device 100 according to the present disclosure includes a display panel 110, a cover window 120, a back plate 130, a metal plate 140, a frame 150, and a molding member 160.

The display panel 110 is a panel for displaying images to a user. In the display panel 110, a display element which displays images, a driving element which drives the display element, and wiring lines which transmit various signals to the display element and the driving element may be disposed.

The display element may be defined in different manners depending on the type of the display panel 110. For example, when the display panel 110 is an organic light emitting display panel 110, the display element may be an organic light emitting diode which includes an anode, an organic emission layer, and a cathode. For example, when the display panel 110 is a liquid crystal display panel, the display element may be a liquid crystal display element. Hereinafter, even though the display panel 110 is assumed as an organic light emitting display panel, the display panel 110 is not limited to the organic light emitting display panel.

The display panel 110 includes an active area AA and a non-active area.

The active area AA is an area where images are displayed in the display panel 110. In the active area AA, a plurality of sub pixels SP which configure a plurality of pixels and a driving circuit for driving the plurality of sub pixels SP may be disposed.

The plurality of sub pixels SP is minimum units which configure the active area AA and a display element may be disposed in each of the plurality of sub pixels SP. For example, an organic light emitting diode which includes an anode, an organic emission layer, and a cathode may be disposed in each of the plurality of sub pixels SP, but it is not limited thereto. Further, the driving circuit for driving the plurality of sub pixels SP may include a driving element, a wiring line, and the like. For example, the driving circuit may be configured by a thin film transistor, a storage capacitor, a gate line, and a data line, but is not limited thereto.

The non-active area is an area in which no image is displayed. The non-active area may refer to an outer peripheral portion of the display panel 110 which encloses the active area AA. The non-active area may overlap the black matrix BM. In the non-active area, various wiring lines, circuits, and the like for driving an organic light emitting diode in the active area AA are disposed. For example, in the non-active area, a link line which transmits signals to the plurality of sub pixels SP and driving circuits of the active area AA or a driving IC (D-IC) such as a gate driver IC or a data driver IC may be disposed, but it is not limited thereto.

The non-active area includes a first non-active area NA1, a bending area BA, and a second non-active area NA2.

The first non-display area NA1 is an area which encloses the active area AA and extends from the active area AA. The bending area BA may extend from one side of the first non-active area NA1 and may be bent. The second non-active area NA2 is an area which extends from the bending area BA to be disposed below the active area.

In the meantime, referring to FIGS. 1A, 1B, and 3C, the first non-active area NA1 and the second non-active area NA2 are disposed on the same plane as the active area AA or disposed to be parallel to the active area AA and maintain a flat state. For example, the first non-active area NA1 is disposed to be flat on the same plane as the active area AA and the second non-active area NA2 may be disposed below the active area AA to be parallel to the active area AA and be flat. Therefore, the active area AA, the first non-active area NA1, and the second non-active area NA2 may be referred to as non-bending areas, but are not limited thereto.

Referring to FIGS. 1A and 1B, the driving IC D-IC is disposed in the second non-active area NA2. The driving IC D-IC may supply a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. The driving IC D-IC may output a data signal through the plurality of data lines. For example, in the second non-active area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel 110 in a chip on panel (COP) manner to be connected to the display panel 110 or is disposed in a separate flexible film to be connected to the display panel 110 in a chip on film (COF) manner. In the display device 100 according to the exemplary embodiment of the present disclosure, it is assumed that the driving IC D-IC is disposed in the COP manner, but it is not limited thereto.

Referring to FIGS. 1A and 1B, as the display panel 110 is bent, the driving IC D-IC disposed in the second non-active area NA2 is disposed below the active area AA. For example, the driving IC D-IC and the printed circuit board connected to the pad unit of the display panel 110 move to the rear surface of the display panel 110 and overlap the active area AA. Therefore, as seen from the top of the display panel 110, circuit elements, such as the driving IC D-IC and the printed circuit board may not be visible. Accordingly, a size of the non-active area which is visible from the top of the display panel 110 is reduced to implement a narrow bezel.

The display panel 110 may include a substrate, a pixel unit, an encapsulation layer, and the like.

The substrate is a base member which supports various components of the display panel 110 and may be configured by an insulating material. The substrate may be formed of a plastic material having flexibility. For example, the substrate may be formed of a plastic material, such as polyimide (PI), but is not limited thereto.

The pixel unit includes a plurality of organic light emitting diodes and a circuit for driving the organic light emitting diodes. The pixel unit may be disposed so as to correspond to the active area AA.

In the meantime, the display panel 110 may be configured by a top emission type or a bottom emission type, depending on an emission direction of light which is emitted from the organic light emitting diode.

According to the top emission type, light emitted from the organic light emitting diode is emitted to an upper portion of the substrate on which the organic light emitting diode is formed. In the case of the top emission type, a reflective layer may be formed below the anode to allow the light emitted from the organic light emitting diode to travel above the substrate, that is, toward the cathode.

According to the bottom emission type, light emitted from the organic light emitting diode is emitted to a lower portion of the substrate on which the organic light emitting diode is formed. In the case of the bottom emission type, the anode may be formed only of a transparent conductive material and the cathode may be formed of the metal material having a high reflectance to allow the light emitted from the organic light emitting diode to travel below the substrate.

Hereinafter, the description will be made under the assumption that the display device 100 according to the exemplary embodiment of the present disclosure is a top emission type, but it is not limited thereto.

The encapsulation layer is disposed so as to cover the pixel unit. The encapsulation layer seals the organic light emitting diode of the pixel unit. The encapsulation layer may protect the organic light emitting diode of the pixel unit from moisture, oxygen, impact, or the like of the outside. The encapsulation layer may be formed by alternately laminating a plurality of inorganic layers and a plurality of organic layers. For example, the inorganic layer may be formed of an inorganic material such as silicon nitride (SiNx), silicon oxide (SiOx), and aluminum oxide (AlOx) and the organic layer may be formed of epoxy-based or acrylic-based polymer, but they are not limited thereto.

Referring to FIGS. 2A to 3C, the cover window 120 is disposed on the front surface of the display panel 110. The cover window 120 may be a component which is exposed to the outer periphery of the display device 100 and protect the display device 100 from external shock or scratches. Further, the cover window 120 may protect the display device 100 from moisture permeating from the outside. The cover window 120 may be formed of a glass or a plastic material having a flexibility, but is not limited thereto.

A black matrix BM is disposed below the cover window 120. The black matrix BM may be disposed along the circumference of the cover window 120 at the other periphery of the cover window 120. At this time, the area in which the black matrix BM is disposed may correspond to the first non-active area NA1. The black matrix BM may be formed of a material having a low permeability. Therefore, the black matrix BM may suppress various components disposed below the first non-active area NA1 from being visible to the outside. Further, the black matrix BM is formed of a material having a conductivity to discharge static electricity of the cover window 120.

The black matrix BM may be configured by chrome (Cr), graphite, or resin including conductive particles. Here, the resin may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. Further, the conductive particle may also be formed of any one of molybdenum (Mo), chrome (Cr), titanium (Ti), nickel (Ni), neodymium (Nd), copper (Cu), and an alloy of silver (Ag) and magnesium (Mg), but is not limited thereto.

Referring to FIGS. 2A to 3C, a polarizer POL is disposed between the display panel 110 and the cover window 120. The polarizer POL may be disposed on the front surface of the display panel 110. The polarizer POL selectively transmits light to reduce the reflection of external light which is incident onto the display panel 110. Specifically, the display panel 110 includes various metal materials applied to the semiconductor element, the wiring line, and the organic light emitting diode. Therefore, the external light incident onto the display panel 110 may be reflected from the metal material so that the visibility of the display device 100 may be reduced due to the reflection of the external light. In contrast, when the polarizer POL is disposed, the polarizer POL suppresses the reflection of the external light so that the outdoor visibility of the display device 100 may be increased. However, the polarizer POL may be omitted depending on an implementation example of the display device 100, but it is not limited thereto.

A first adhesive layer AD1 is disposed between the polarizer POL and the cover window 120 and a second adhesive layer AD2 is disposed between the polarizer POL and the display panel 110. The first adhesive layer AD1 may bond the cover window 120 and the polarizer POL and the second adhesive layer AD2 may bond the polarizer POL and the display panel 110. As a result, the first adhesive layer AD1 and the second adhesive layer AD2 bond the display panel 110 and the cover window 120. The first adhesive layer AD1 and the second adhesive layer AD2 may be formed as transparent adhesive layers so that an image of the display panel 110 is visible. For example, the first adhesive layer AD1 and the second adhesive layer AD2 may be formed of optical clear adhesives (OCA), but are not limited thereto.

The back plate 130 is disposed below the display panel 110. The back plate 130 may be disposed so as to support the display panel 110. For example, when the substrate of the display panel 110 is formed of a plastic material such as polyimide, due to the flexible property, a separate component for protecting the substrate may be necessary. Therefore, a support substrate which is formed of glass is disposed below the substrate to perform a manufacturing process of the display device 100 and the support substrate may be separated to be released after completing the manufacturing process. However, a component for supporting the substrate is necessary even after releasing the support substrate, so that a back plate 130 for supporting the substrate may be disposed below the display panel 110.

The back plate 130 may include a plastic material. For example, the back plate 130 may be formed of a plastic thin film formed of polyimide (PI), polyethylene naphthalate (PEN), polyethylene terephthalate (PET), or a combination of the polymers.

A third adhesive layer AD3 is disposed between the display panel 110 and the back plate 130. The third adhesive layer AD3 may bond the display panel 110 and the back plate 130. The third adhesive layer AD3 may be formed of a pressure sensitive adhesive (PSA), but is not limited thereto.

The metal plate 140 is disposed below the back plate 130. The metal plate 140 may protect the components of the display device 100 from external shocks. Further, the metal plate 140 serves as a ground to suppress the static electricity entering the display device 100 or easily discharge residual charges accumulated in the display device 100 to the outside. Further, the metal plate 140 may easily discharge heat generated in the display device 100 to the outside. The metal plate 140 may be formed of a metal material having excellent thermal conductivity, electrical conductivity, and mechanical rigidity. For example, the metal plate 140 may be configured by copper (Cu) or stainless steel (SUS), but is not limited thereto.

A fourth adhesive layer AD4 may be disposed between the back plate 130 and the metal plate 140. The fourth adhesive layer AD4 may bond the back plate 130 and the metal plate 140 to each other. The fourth adhesive layer AD4 may be formed of a pressure sensitive adhesive (PSA), but is not limited thereto.

Referring to FIG. 3C, an additional back plate 130A and an additional metal plate 140A are disposed below the metal plate 140 corresponding to the bending area BA.

The additional back plate 130A and the additional metal plate 140A may supplement the rigidity of the second non-active area NA2 of the display panel 100 disposed in the second non-active area. In the meantime, the additional back plate 130A and the additional metal plate 140A may be disposed so as not to overlap the bending area BA. Therefore, the thicknesses of the configurations disposed in the bending area BA may be minimized and a neutral plane of the bending area BA is easily controlled to ensure the flexibility of the bending area.

Referring to FIG. 3C, a fifth adhesive layer AD5 is disposed between the metal plate 140 and the additional metal plate 140A and a sixth adhesive layer AD6 is disposed between the additional metal plate 140A and the additional back plate 130A. The fifth adhesive layer AD5 may bond between the metal plate 140 and the additional metal plate 140A and the sixth adhesive layer AD6 may bond between the additional metal plate 140A and the additional back plate 130A. For example, the fifth adhesive layer AD5 and the sixth adhesive layer AD6 may be formed of a pressure sensitive adhesive (PSA), but are not limited thereto.

The second non-active area NA2 of the display panel 110 is disposed below the additional back plate 130A. Further, a seventh adhesive layer AD7 is disposed between the additional back plate 130A and the second non-active area NA2 of the display panel 110. The seventh adhesive layer AD7 may bond between the additional back plate 130A and the second non-active area NA2 of the display panel 110. For example, the seventh adhesive layer AD7 may be formed of a pressure sensitive adhesive (PSA), but is not limited thereto.

A frame 150 is disposed below the metal plate 140. The frame 150 may be disposed along an outer periphery of the display device 100 below the metal plate 140. Therefore, the frame 150 may reinforce the rigidity of the outer periphery of the display device 100 while covering the outer periphery of the display device 100. Further, the frame 150 is partially exposed from the molding member 160 as illustrated in FIG. 1B to serve as a fastening unit with the component disposed below the frame 150.

For example, the frame 150 is formed of plastic formed by polyimide (PI), polyethylene naphthalate (PEN), polyethylene terephthalate (PET), or combinations of these polymers or a metal, such as copper (Cu) or stainless steel (SUS) to reinforce the rigidity of the outer periphery of the display device 100. However, it is not limited thereto.

The frame 150 includes a first edge portion 151, a plurality of second edge portions 152, and an opening 150OP.

The first edge portion 151 is a portion corresponding to the bending area BA in the frame 150. The first edge portion 151 may correspond to a corner of the display device 100 in which the bending area BA is disposed. For example, as illustrated in FIG. 1B, in the display device 100 in which one bending area BA is disposed, one first edge portion 151 may be disposed, but is not limited thereto.

Referring to FIG. 3C, the first edge portion 151 may be attached to the second non-active area NA2 of the display panel 110. Therefore, the first edge portion 151 may be configured to support the second non-active area NA2 of the display panel 110 corresponding to the bending area BA. In the meantime, the first edge portion 151 may be attached to the second non-active area NA2 using an adhesive material, such as a pressure sensitive adhesive (PSA), but is not limited thereto.

The plurality of second edge portions 152 are portions of the frame 150 excluding the first edge portion 151. The plurality of second edge portions 152 may correspond to corners of the display device 100 in which the bending area BA is not disposed. For example, as illustrated in FIG. 1B, when an outer peripheral shape of the display device 100 has a rectangular shape having four corners and the bending area BA is disposed in only one corner, the plurality of second edge portions 152 may be disposed to correspond to three corners in which the bending area BA is not disposed.

Referring to FIGS. 3A and 3B, the plurality of second edge portions 152 may be attached onto a rear surface of the metal plate 140. Therefore, the plurality of second edge portions 152 may be configured to support the rear surface of the display panel 110 in which the bending area BA is not disposed. In the meantime, the plurality of second edge portions 152 may be attached to the rear surface of the metal plate 140 using an adhesive material, such as a pressure sensitive adhesive (PSA), but is not limited thereto.

The opening 150OP is a space enclosed by the plurality of second edge portions 152, the first edge portion 151, and the plurality of second edge portions 152. The opening 150OP is a space enclosed by inner surfaces of the plurality of second edge portions 152 and inner surfaces of the first edge portion 151 and the plurality of second edge portions 152. Even though in FIG. 1B, it is illustrated that the frame 150 includes one opening 150OP having a rectangular shape, the shape and the number of openings 150OP may be designed in consideration of components fastened below the frame 150, but it is not limited thereto.

Referring to FIGS. 3A to 3C, a distance between the first edge portion 151 and the metal plate 140 may be different from a distance between the plurality of second edge portions 152 and the metal plate 140. For example, the first edge portion 151 is attached to the second non-active area NA2 of the display panel 110 and the plurality of second edge portions 152 may be attached to the lower portion of the metal plate 152. Further, the second edge portion 152 which is adjacent to the first edge portion 151 may be connected to each other with a step. At this time, the step of the second edge portion 152 adjacent to the first edge portion 151 may be designed in consideration of a thickness difference of a portion in which the display panel 110 is bent toward the rear surface of the metal plate 140 and a portion in which the display panel 110 is not bent toward the rear surface of the metal plate 140. However, it is not limited thereto.

In the meantime, referring to FIG. 3C, the first edge portion 151 includes a first part 151a and a second part 151b. The first part 151a extends downwardly from an uppermost end of the first edge portion 151 and the second part 151b extends from an end of the first part 151a to the outside. The first edge portion 151 may be disposed to have a “L” shaped cross-section by the first part 151a and the second part 151b.

The first edge portion 151 is bent to the rear surface of the metal plate 140 so as not to interfere with components disposed below the display panel 110. For example, as illustrated in FIG. 3C, a first edge portion 151 and a micro coating layer MCL may be disposed in the second non-active area NA2 of the display panel 110. Further, the first part 151a of the first edge portion 151 is disposed to be spaced apart from the micro coating layer MCL. Therefore, the second part 151b of the first edge portion 151 does not interfere with the micro coating layer MCL and may be disposed to extend to an area overlapping the bending area BA.

Referring to FIGS. 2A to 3C, the frame 150 further includes a plurality of protrusions 150P. The plurality of protrusions 150P are disposed to protrude from side surfaces of the first edge portion 151 and the plurality of second edge portions 152. The plurality of protrusions 150P are disposed on an outer surface of the first edge portion 151 and outer surfaces of the plurality of second edge portions 152 in the frame 150. That is, the plurality of protrusions 150P may be disposed in both the first edge portion 151 and the plurality of second edge portions 152.

Referring to FIG. 3C, each of the plurality of protrusions disposed in the first edge portion 151 may protrude to be parallel to the plane on which the second part 151b is disposed. Referring to FIGS. 3A and 3B, each of the plurality of protrusions 150P disposed in the plurality of second edge portions 152 may protrude to be parallel to the plane on which the plurality of second edge portions 152 is disposed. For example, as illustrated in FIGS. 1B and 3C, the plurality of protrusions disposed in the second part 151b of the first edge portion 151 which is disposed on an X-Y plane and extends to an X-axis direction may protrude to a Y-axis direction on the outer surface of the first edge portion 151. The plurality of protrusions 150P disposed in the second edge portion 152 which is disposed on the X-Y plane and extends to the Y-axis direction, as illustrated in FIGS. 2A and 2B, among the plurality of second edge portions 152, may protrude to the X-axis direction from the outer surface of the second edge portion 152. The plurality of protrusions 150P disposed in the second edge portion 152 which is disposed on the X-Y plane and extends to the X-axis direction, among the plurality of second edge portions 152, may protrude to the Y-axis direction from the outer surface of the second edge portion 152.

In the meantime, referring to FIGS. 2A to 3C, the plurality of protrusions 150P may be portions which protrude to the outermost side in the frame 150. The plurality of protrusions 150P may be configurations which are disposed at the outermost side, among components enclosed by the molding member 160 below the cover window 120. At this time, the molding member 160 is disposed so as to enclose all the plurality of protrusions 150P of the frame 150. That is, the molding member 160 is disposed so as to enclose all a top surface, a bottom surface, and a side surface of the plurality of protrusions 150P which protrudes from the side surface of the frame 150. Therefore, the plurality of protrusions 150P may increase a contact area between the molding member 160 and the frame 150.

Referring to FIGS. 2A to 3C, a plurality of holes 150H are disposed in the frame 150. The plurality of holes 150H is disposed in a part in which the frame 150 is covered by the molding member 160. As illustrated in FIGS. 2A to 3C, the plurality of holes 150H may pass through the thickness direction of the frame 150. The molding member 160 may be filled in the plurality of holes 150H. Therefore, the plurality of holes 150H may increase a contact area between the molding member 160 and the frame 150. In the meantime, the plurality of holes 150H may not completely pass through the frame 150 in the thickness direction, but may have a groove shape obtained by removing a part of the frame 150 in the thickness direction, but is not limited thereto.

The molding member 160 seals the cover window 120, the display panel 110, the back plate 130, the metal plate 140, and the frame 150. Specifically, the molding member 160 may be disposed so as to enclose parts of a lower portion of the cover window 120, a side surface of the display panel 110, a side surface of the back plate 130, a side surface of the metal plate 140, and a side surface and a part of a bottom surface of the frame 150. The molding member 160 may suppress the permeation of the moisture or oxygen into the display device 100. Further, the molding member 160 may protect components of the display device 100 and relieve shocks applied to the display device 100.

For example, the molding member 160 is formed by a process of removing a mold, after filling and curing the mold which is disposed to enclose a side surface of the cover window 120 and expose a side surface of the display panel 110, a side surface of the back plate 130, a side surface of the metal plate 140, a side surface of the frame 150, and a part of a bottom surface of the frame 150 with a material for forming the molding member 160. However, the method of forming the molding member 160 is not limited thereto.

The molding member 160 may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

In the display device, a separate cover unit may be disposed below the cover window so as to protect the components of the display device, such as a display panel. However, when a separate cover unit is disposed, in order to minimize or at least reduce the interference between the display panel and the cover unit, the cover unit is coupled to be spaced apart from the display panel with a predetermined distance. Therefore, in the display device in which a separate cover unit is disposed below the cover window, it is difficult to implement a narrow bezel due to the space between the display panel and the cover unit.

In the display device 100 according to the exemplary embodiment of the present disclosure, a molding member 160 which seals the components of the display device 100 is disposed below the cover window 120 to minimize the size of the bezel area. Specifically, the display device 100 according to the exemplary embodiment of the present disclosure seals the components of the display device 100 by means of the molding member 160. The molding member 160 may be disposed so as to enclose a side surface of the display panel 110, a side surface of the back plate 130, a side surface of the metal plate 140, and a side surface of the frame 150 from a lower portion of the cover window 120 and cover a part of the bottom surface of the frame 150. That is, the molding member 160 is integrally formed with the display device 100 while directly enclosing the components of the display device 100 so that a separate configuration, such as a cover unit for protecting the components of the display device 100, will be omitted. Therefore, a separate space for minimizing the interference between a separate configuration, such as a cover unit and components of the display device 100 may be also omitted so that the size of the first non-active area NA1, that is, the bezel area, may be minimized or at least reduced. Accordingly, in the display device 100 according to the exemplary embodiment of the present disclosure, a molding member 160 which seals the components of the display device 100 is disposed below the cover window 120 to minimize or at least reduce the size of the bezel area and implement a narrow bezel.

In the meantime, in the display device 100 according to the exemplary embodiment of the present disclosure, the molding member 160 is formed of resin so that the molding member 160 may buffer an external impact on the components of the display device 100 sealed by the molding member 160, such as the display panel 110. Therefore, in the display device 100 according to the exemplary embodiment of the present disclosure, an additional effect of buffering the external impact applied to the display device 100 by the molding member 160 formed of resin may be provided.

In the display device 100 according to the exemplary embodiment of the present disclosure, the plurality of protrusions 150P is disposed in the frame 150 to improve the bonding strength of the molding member 160.

Specifically, in the display device 100 according to the exemplary embodiment of the present disclosure, the plurality of protrusions 150P is disposed on the side surface of the frame 150. The plurality of protrusions 150P may be configurations which are disposed at the outermost side, among components enclosed by the molding member 160 below the cover window 120. Further, the molding member 160 is disposed so as to enclose all the plurality of protrusions 150P. Accordingly, the plurality of protrusions 150P may increase a contact area between the molding member 160 and the frame 150. As described above, when the plurality of protrusions 150P are disposed in the frame 150, a plurality of contact surfaces may be provided in various directions, as compared with an example that all the side surfaces of the frame 150 protrude. Therefore, as the plurality of protrusions 150P are disposed in the frame, the plurality of protrusions 150P may improve the binding force to the molding member 160 in various directions. Specifically, the plurality of protrusions 150P are disposed to protrude from the frame 150P disposed on the X-Y plane to the X-axis direction or the Y-axis direction so that the binding force to the molding member 160 may be improved in a Z-axis direction perpendicular to the X-axis direction and the Y-axis direction. Therefore, the separation between the molding member 160 and the frame 150 is further minimized and the bonding strength of the molding member 160 and the frame 150 is further improved. Accordingly, in the display device 100 according to the exemplary embodiment of the present disclosure, the plurality of protrusions 150P is disposed in the frame 150 to improve the bonding strength of the molding member 160.

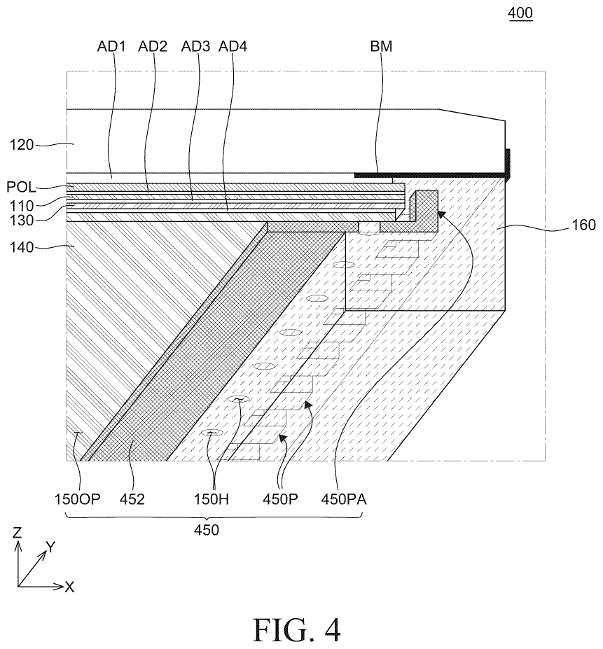

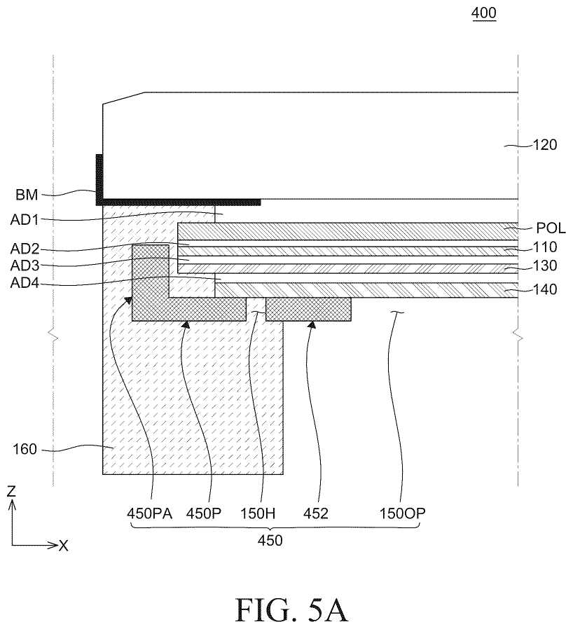

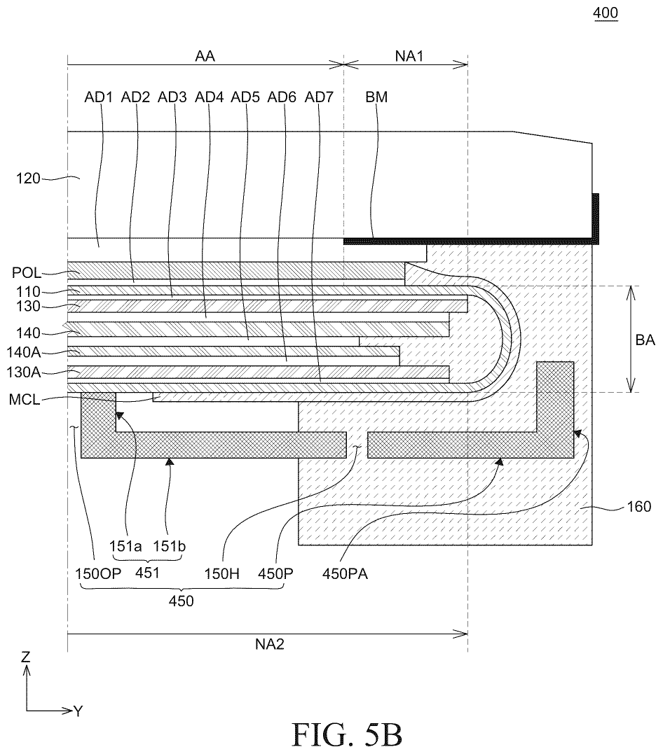

FIG. 4 is a perspective cross-sectional view of a display device according to another exemplary embodiment of the present disclosure. FIGS. 5A and 5B are cross-sectional views of a display device according to another exemplary embodiment of the present disclosure. In FIGS. 4 to 5B, for the convenience of description, among components of a display device 400, only a display panel 110, a cover window 120, a back plate 130, a metal plate 140, a frame 450, and a molding member 160 are illustrated. The display device 400 of FIGS. 4 to 5B is the same as the display device 100 of FIGS. 1A to 3C, except that a frame 450 further includes an additional protrusion 450PA, so that a redundant description will be omitted.

Referring to FIGS. 4 to 5B, the frame 450 further includes an additional protrusion 450PA. The additional protrusion 450PA protrudes from end portions of the plurality of protrusions 450P to the Z-axis direction. The additional protrusion 450PA may protrude from end portions of the plurality of protrusions 450P to an upper portion of the frame 450. In the meantime, in FIGS. 4 to 5B, it is illustrated that the additional protrusion 450PA protrudes toward the upper portion of the frame 450 from an end portion of each of the plurality of protrusions 450P along the Z-axis direction. However, the additional protrusion 450PA may protrude toward the lower portion of the frame 450 along the Z-axis direction from the end portion of each of the plurality of protrusions 450P.

For example, the plurality of protrusions 450 disposed in the second part 151b of the first edge portion 451 which is disposed on the X-Y plane and extends to the X-axis direction may protrude to the Y-axis direction from the outer surface of the first edge portion 451. Further, the additional protrusion 450PA may protrude to the Z-axis direction from the end portion of each of the plurality of protrusions 450P. A plurality of protrusions 450P disposed on a second edge portion 452 which is disposed on the X-Y plane and extends to the Y-axis direction, among the plurality of second edge portions 452, may protrude to the X-axis direction from the outer surface of the second edge portion 452. The additional protrusion 450PA may protrude to the Z-axis direction from the end portion of each of the plurality of protrusions 450P. A plurality of protrusions 450P disposed on a second edge portion 452 which is disposed on the X-Y plane and extends to the X-axis direction, among the plurality of second edge portions 452, may protrude to the Y-axis direction from the outer surface of the second edge portion 452. The additional protrusion 450PA may protrude to the Z-axis direction from the end portion of each of the plurality of protrusions 450P.

In the display device 400 according to another exemplary embodiment of the present disclosure, the additional protrusion 450P is further disposed in the frame 450 to further improve the bonding strength of the molding member 160.

Specifically, in the display device 400 according to another exemplary embodiment of the present disclosure, the plurality of protrusions 450P is disposed on the side surface of the frame 450 and the additional protrusion 450PA is further disposed in an end portion of each of the plurality of protrusions 450P. Accordingly, the plurality of protrusions 450P and the additional protrusion 450PA may further increase a contact area between the molding member 160 and the frame 450. Therefore, the plurality of protrusions 450P and the additional protrusion 450PA improve the binding force to the molding member 160 in various directions. Specifically, the plurality of additional protrusions 450PA are disposed so as to protrude from the end portion of each of the plurality of protrusions 450P to the Z-axis direction to further improve the binding force to the molding member 160 in the X-axis direction and the Y-axis direction perpendicular to the Z-axis direction. Therefore, the separation between the molding member 160 and the frame 450 is further minimized and the bonding strength of the molding member 160 and the frame 450 may be further improved. Accordingly, in the display device 400 according to another exemplary embodiment of the present disclosure, the plurality of protrusions 450P and the additional protrusion 450PA are disposed in the frame 450 to further improve the bonding strength of the molding member 160.

The exemplary embodiments of the present disclosure can also be described as follows:

According to an aspect of the present disclosure, a display device includes a cover window; a display panel which includes an active area disposed below the cover window and including a plurality of pixels disposed therein, a first non-active area which encloses the active area, and a bending area which extends from one side of the first non-active area to be bent; a frame which is disposed below the display panel and includes a plurality of protrusions disposed on a side surface; and a molding member which is disposed below the cover window along an end of the cover window and is disposed so as to cover a side surface of the display panel, a side surface of the frame in which the plurality of protrusions is disposed, and a part of a bottom surface of the frame.

The display panel may further include a second non-active area which extends from the bending area to be disposed below the active area, and the molding member may be disposed so as to cover the bending area and a part of the second non-active area.

The frame may include a first edge portion corresponding to the bending area, a plurality of second edge portions which is connected to the first edge and is disposed to have a step with the first edge portion, and an opening which is disposed so as to be enclosed by the first edge portion and the plurality of second edge portions.

The plurality of protrusions may be disposed on an outer surface of the first edge portion and outer surfaces of the plurality of second edge portions.

The first edge portion may include a first part which extends downwardly from an uppermost end of the first edge portion, and a second part which extends from an end portion of the first part to the outside.

The display device may further comprise a micro coating layer which is disposed on the display panel so as to overlap at least the bending area.

The first part may be disposed to be spaced apart from the micro coating layer.

Each of the plurality of protrusions disposed in the plurality of second edge portions may protrude to be parallel to a plane on which the plurality of second edge portions is disposed.

The display device may further comprise a metal plate disposed between the display panel and the frame.

The plurality of second edge portions may be attached to the metal plate.

The frame may further include an additional protrusion which protrudes from an end portion of each of the plurality of protrusions to an upper portion of the frame.

The molding member may be disposed to enclose all the plurality of protrusions.

The frame may further include a plurality of holes disposed in a portion covered by the molding member.

The display device may further comprise a polarizer disposed between the cover window and the display panel, a back plate disposed between the display panel and the frame, and a metal plate disposed between the back plate and the frame.

The molding member may be disposed so as to enclose a side surface of the polarizer, a side surface of the display panel, a side surface of the back plate, a side surface of the metal plate, a side surface of the frame, and a part of a bottom surface of the frame.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims. and all the technical concepts in the equivalent scope thereof should be construed as falling within the scope of the present disclosure.

What is claimed is:

1. A display device, comprising:
a cover window;
a display panel that includes an active area that is below the cover window and includes a plurality of pixels, a first non-active area that encloses the active area, and a bending area that extends from one side of the first non-active area and is configured to be bent;
a frame that is disposed below the display panel and includes a plurality of protrusions on a side surface; and
a molding member that is disposed below the cover window along an end of the cover window and covers a side surface of the display panel, a side surface of the frame in which the plurality of protrusions are disposed, and a part of a bottom surface of the frame.

2. The display device according to claim 1, wherein the display panel further includes a second non-active area that extends from the bending area and is disposed below the active area, and the molding member covers the bending area and a part of the second non-active area.

3. The display device according to claim 1, wherein the frame includes:
a first edge portion corresponding to the bending area;
a plurality of second edge portions that are connected to the first edge portion and have
a step with the first edge portion; and
an opening that is enclosed by the first edge portion and the plurality of second edge portions.

4. The display device according to claim 3, wherein the plurality of protrusions are on an outer surface of the first edge portion and outer surfaces of the plurality of second edge portions.

5. The display device according to claim 3, wherein the first edge portion includes:
a first part that extends downwardly from an uppermost end of the first edge portion; and
a second part that extends from an end portion of the first part to the outside.

6. The display device according to claim 5, further comprising:
a micro coating layer on the display panel, the micro coating layer overlapping at least the bending area,
wherein the first part is spaced apart from the micro coating layer.

7. The display device according to claim 3, wherein each of the plurality of protrusions disposed in the plurality of second edge portions protrudes to be parallel to a plane on which the plurality of second edge portions are disposed.

8. The display device according to claim 3, further comprising:
a metal plate between the display panel and the frame,
wherein the plurality of second edge portions are attached to the metal plate.

9. The display device according to claim 1, wherein the frame further includes an additional protrusion that protrudes from an end portion of each of the plurality of protrusions to an upper portion of the frame.

10. The display device according to claim 1, wherein the molding member encloses all the plurality of protrusions.

11. The display device according to claim 1, wherein the frame further includes a plurality of holes in a portion covered by the molding member.

12. The display device according to claim 1, further comprising:
a polarizer between the cover window and the display panel;
a back plate between the display panel and the frame; and
a metal plate between the back plate and the frame,
wherein the molding member encloses a side surface of the polarizer, a side surface of the display panel, a side surface of the back plate, a side surface of the metal plate, a side surface of the frame, and a part of a bottom surface of the frame.
